(19) United States
(12) Patent Application Publication
(10) Pub. No.: US 2016/0036200 A1
(43) Pub. Date: Feb. 4, 2016

(54) OSCILLATION DEVICE

(71) Applicant: CANON KABUSHIKI KAISHA, Tokyo (JP)

(72) Inventor: Yoshinori Tateishi, Naka-gun (JP)

(21) Appl. No.: 14/808,840

(22) Filed: Jul. 24, 2015

(30) Foreign Application Priority Data
Jul. 31, 2014 (JP) 2014-156795
Jun. 15, 2015 (JP) 2015-120404

(51) Int. Cl. H01S 5/10; H01S 5/14; H01S 5/34

(52) U.S. Cl. CPC H01S 5/1003; H01S 5/3402; H01S 5/146

(57) ABSTRACT

An oscillation device that produces an oscillating electromagnetic wave includes a resonator, a conducting wall, and a first conductor layer. The resonator includes a waveguide structure for resonating the electromagnetic wave and a dielectric layer. The waveguide structure includes a second conductor layer, a gain medium disposed on the second conductor layer, and a third conductor layer disposed on the gain medium. The dielectric layer is disposed on the second conductor layer and along a side of the gain medium. The conducting wall is separated from the gain medium by the dielectric layer and is disposed at a positions of a node of an electric field of a standing electromagnetic wave in the waveguide structure in the resonance axis direction. An optical distance between the side of the gain medium and the conducting wall is equal to or smaller than one fourth of a wavelength of the electromagnetic wave.

### BACKGROUND OF THE INVENTION

1. Field of the Invention

The present invention relates to an oscillation device that produces an oscillating electromagnetic wave.

2. Description of the Related Art

Terahertz waves are electromagnetic waves in a frequency range from a millimeter band to a terahertz band (30 GHz or more and 30 THz or less). For current injection terahertz wave oscillation devices, a structure that uses the gain of electromagnetic waves based on intersubband transition of electrons in a semiconductor quantum well structure, such as those of quantum cascade lasers (QCLs) is being examined. An example of an oscillation device including the QCL is a device provided with a double-sided-metal (DSM) waveguide type resonator having clads whose real part of dielectric constant is negative metal and a core which is an active layer sandwiched between the clads.

To obtain oscillation at a desired frequency with long-wavelength lasers (oscillation devices) including such a resonator, stabilization of the frequency has been attempted. U.S. Patent Application Publication No. 2006/0215720 discloses a distributed Bragg reflector (DBR) structure that periodically changes the dope amount of a high dope semiconductor clad or core that constitutes a waveguide type resonator structure. This uses the fact that changing the dope amount periodically will periodically change the refractive index. U.S. Patent Application Publication No. 2010/0232457 discloses a method for to stabilizing the operating point and the oscillating frequency by connecting the upper and lower clads with a resistor at portions where the surface currents of upper and lower clads that constitute a DSM waveguide type resonator structure become the maximum to stabilize the potential difference between the clads.

The structure disclosed in U.S. Patent Application Publication No. 2006/0215720 needs a large level-difference in refractive index to form the DBR. To obtain the large level-difference in refractive index, a dope amount is increased. However, when the dope amount is increased, absorption loss in the waveguide can be increased. With the oscillation device disclosed in U.S. Patent Application Publication No. 2010/0232457, the stability of operation is decreased due to the influence of the resistor and so on, resulting in insufficient stability of the oscillating frequency.

### SUMMARY OF THE INVENTION

In an aspect of the present invention, an oscillation device that produces an oscillating electromagnetic wave includes a resonator, at least one conducting wall, and a first conductor layer that electrically connects the waveguide structure and the conducting wall. The resonator includes a waveguide structure for resonating the electromagnetic wave along a resonance axis direction and a dielectric layer. The waveguide structure includes a second conductor layer, a gain medium disposed on the second conductor layer, and a third conductor layer disposed on the gain medium. The dielectric layer is disposed on the second conductor layer and along a side of the gain medium. The conducting wall is separated from the gain medium by the dielectric layer and is disposed at a position of a node of an electric field of the electromagnetic wave appearing to be stationary in the waveguide structure in the resonance axis direction. An optical distance between the side of the gain medium and the conducting wall is equal to or smaller than one fourth of a wavelength of the electromagnetic wave.

Further features of the present invention will become apparent from the following description of exemplary embodiments with reference to the attached drawings.

### BRIEF DESCRIPTION OF THE DRAWINGS

FIG. 1 is a perspective view of the configuration of an oscillation device according to an embodiment of the present invention.

FIG. 2 is a top view of the configuration of an oscillation device of a first exemplary embodiment.

FIG. 3 is a graph showing the relationship between the frequencies of electromagnetic waves generated by oscillation devices of the first and second exemplary embodiments and those of conventional oscillation devices and the length of the resonator.

FIG. 4A is a graph showing the relationship between the length of a proximal region and waveguide loss.

FIG. 4B is a graph showing the relationship between the width of a conducting wall and waveguide loss.

FIG. 5 is a top view of an oscillation device of the second exemplary embodiment.

FIG. 6 is a top view of a modification of the oscillation device of the second exemplary embodiment.

FIG. 7 is a top view of the configuration of an oscillator including the oscillation device of the second exemplary embodiment.

FIG. 8 is a perspective view of the configuration of an oscillation device of a fourth exemplary embodiment.

FIG. 9 is a top view of the configuration of an oscillation device of a fifth exemplary embodiment.

FIG. 10 is a top view of the configuration of a conventional oscillation device.

### DESCRIPTION OF THE EMBODIMENTS

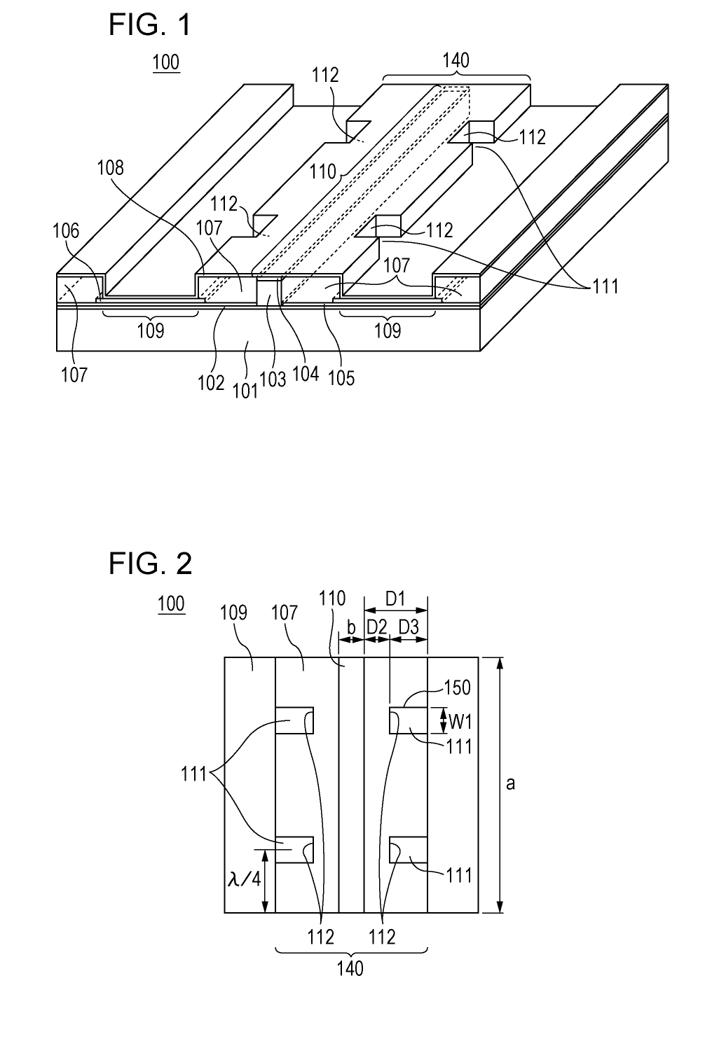

An oscillation device 100 according to an embodiment of the present invention will be described with reference to FIG. 1. FIG. 1 is an external perspective view of the oscillation device 100 (hereinafter referred to as a device 100). The device 100 includes a substrate 101, a first conductor layer 108, a capacitor 109, a resonator 140, and a plurality of conducting walls 112. The device 100 produces oscillating electromagnetic waves (terahertz waves) in a frequency range of 30 GHz or more and 30 THz or less.

The frequency of oscillating electromagnetic waves produced by an oscillation device including a resonator mainly depends on the configuration of a waveguide structure of the resonator. Oscillation devices are designed to generate electromagnetic waves with a desired oscillating frequency f_{g}. However, the resonant mode of electromagnetic waves resonating in the waveguide structure, that is, a λ_{g}/2 resonant mode, a λ_{g} resonant mode, or another resonant mode, cannot be controlled, making the frequency of generated electromagnetic waves unstable. The device 100 of this embodiment obtains a stable oscillating frequency f_{g} of electromagnetic waves using the conducting walls 112.

The components of the device 100 will be described. The resonator 140 is a waveguide resonator including a waveguide structure 110 (hereinafter referred to as a waveguide 110) with which electromagnetic waves resonate and a dielectric layer (an interlayer insulating layer) 107.

The waveguide 110 includes a second conductor layer 102, a gain medium 103 disposed on the second conductor layer 102, and a third conductor layer 104 disposed on the gain medium 103. In other words, the waveguide 110 is a double-sided-metal (DSM) plasmon waveguide structure in which the gain medium 103 is disposed between the second conductor layer 102 and the third conductor layer 104. Specifically, the waveguide 110 is formed such that, a core, which is a not-densely doped portion of the gain medium 103, is sandwiched between cladding portions including the second conductor layer 102 and the third conductor layer 104, respectively. The cladding portions are a stack of the second conductor layer 102 and a densely doped semiconductor layer in the gain medium 103 and a stack of the third conductor layer 104 and a densely doped semiconductor layer in the gain medium 103, respectively.

The gain medium 103 includes a semiconductor multilayer that generates terahertz waves and has a gain in the frequency range of the generated terahertz waves. Specific examples of the gain medium 103 include a resonant tunneling diode (RTD) and a Gunn diode. This embodiment includes the RTD. The oscillation device 100 is configured to apply bias to the gain medium 103 by applying bias in between the second conductor layer 102 and the third conductor layer 104 with a bias circuit (not shown) including an external power source.

The second conductor layer 102 and the third conductor layer 104 each include a negative dielectric constant medium whose real part of dielectric constant is negative. Specifically, the second conductor layer 102 and the third conductor layer 104 may be made of metal, such as titanium (Ti), molybdenum (Mo), tungsten (W), silver (Ag), gold (Au), copper (Cu), aluminum (Al), or an alloy of gold and indium (AuIn). The second conductor layer 102 and the third conductor layer 104 may also be made of semimetal, such as bismuth (Bi), antimony (Sb), indium tin oxide (ITO), or erbium arsenide (ErAs), or a densely doped semiconductor. Alternatively, the second conductor layer 102 and the third conductor layer 104 may be a stack of the above metal, semimetal, a densely doped semiconductor, and so on.

The frequencies of electromagnetic waves generated using the second conductor layer 102 and the third conductor layer 104 are brought close to λ_{g}/2 or less, more preferably, λ_{g}/10 or less, where λ_{g} is a wavelength (oscillating wavelength) corresponding to the oscillating frequency f_{g} defined by the configuration of the waveguide 110 of the resonator 140. This configuration allows electromagnetic waves in the range of the desired oscillating frequency f_{g} to resonate in the waveguide 110 in a surface plasmon mode in which no diffraction limit is present. With the waveguide 110 whose both ends are open, the oscillating wavelength λ_{g} is defined by setting the length a of the waveguide 110 in the direction of the resonance axis of the electromagnetic waves to an integral multiple of λ_{g}/2, as is known in a laser technique. The direction of the resonance axis of the electromagnetic waves of the waveguide 110 is the same as the direction of propagation of the electromagnetic waves, that is, the longitudinal direction of the waveguide 110. A direction perpendicular to the resonance axis and the sides of the gain medium 103 is referred to as a widthwise direction. “The sides of the gain medium 103” in this specification are defined as surfaces of the plurality of surfaces of the gain medium 103 intersecting the bottom, which is the surface of the gain medium 103 nearer to the second conductor layer 102 and extending along the resonance axis.

The interlayer insulating layer 107 is a dielectric layer disposed on the sides of the gain medium 103 and separates the capacitor 109 and the proximal regions 111 from the gain medium 103. The interlayer insulating layer 107 is disposed on the second conductor layer 102. The “dielectric” in this specification is a substance having more dielectricity rather than electrical conductivity and acts as an insulator to direct current and has high transmissivity to electromagnetic waves with the desired oscillating frequency f_{g}. Examples of a dielectric that constitutes the dielectric layer 107 include resin, such as benzocyclobutene (BCB), and an inorganic material, such as SiO₂. The dielectric layer 107 may not be filled with a material but may be the air in a space covered with the first conductor layer 108.

The capacitor 109 includes the second conductor layer 102, a dielectric film 105 disposed at the side of the gain medium 103 and on the second conductor layer 102, and a fourth conductor layer 106 disposed on the dielectric film 105. Parts of the capacitor 109 are close to the gain medium 103 to form proximal regions 111. The capacitor 109 of this embodiment has the function of suppressing parasitic oscillation due to the configuration of the power bias circuit, etc. In other words, parts of the capacitor 109 for suppressing parasitic oscillation constitute the proximal regions 111 close to the waveguide 110. The device 100 may have a plurality of capacitors 109.

The capacitor 109 and the waveguide 110 are electrically connected in parallel by the first conductor layer 108. The first conductor layer 108 forms conducting walls 112 along the outer periphery of the proximal regions 111. The conducting walls 112 are side walls of the proximal regions 111 and are disposed so as to intersect a plane including the longitudinal direction (the resonance axis direction) and the widthwise direction of the waveguide 110. Since the interlayer insulating layer 107 is disposed between the proximal regions 111 and the waveguide 110, the proximal regions 111 and the side walls of the waveguide 110 are separated from each other without physical contact. Thus, the gain medium 103 and the conducting walls 112 are separated by the interlayer insulating layer 107. The locations of the proximal regions 111 will be described below.

Although the first conductor layer 108 and the third conductor layer 104 of this embodiment are separate conductor layers, they may be integrated to a single unit, or alternatively, the first conductor layer 108 may have the function of the third conductor layer 104.

The locations of the conducting walls 112 of the proximal regions 111 close to the waveguide 110 and the gain medium 103 will now be described. Electromagnetic waves that propagate through the plasmon waveguide 110 of the resonator 140 generate surface plasmon on the respective surfaces of the second conductor layer 102 and the third conductor layer 104. Surface plasmon involves fluctuations of carriers. Thus, the surface plasmon can be controlled by controlling the fluctuations of carriers or fluctuations of the electric field.

Thus, the conducting walls 112 are disposed at the position of the nodes of the electric field of electromagnetic waves with the desired oscillating frequency f_{g} in the waveguide 110 when the electromagnetic waves appear stationary in the resonance axis direction. The shortest distance D2 between the conducting walls 112 and the waveguide 110 is preferably one fourth of the oscillating wavelength λ_{g} or less in an optical distance.

Here, “the nodes of the electric field of electromagnetic waves” are the nodes of standing waves, which are electromagnetic waves that appear stationary in the waveguide 110, at which the surface current across the waveguide 110 is the maximum.

If an end face of the waveguide 110 is an open end, that is, if the electromagnetic waves that resonate in the waveguide 110 reflect at the open end, the positions of the nodes of the electric field of electromagnetic waves with the oscillating frequency f_{g} are at (−λ_{g}/4+λ_{g}/2, n=1, 2, 3 . . . ) from the end face of the waveguide 110 in the resonance axis direction. If the end face of the waveguide 110 is a fixed end, that is, if the electromagnetic waves that resonate in the waveguide 110 reflect at the fixed end, the positions of the nodes of the electric field of the electromagnetic waves with the oscillating frequency f_{g} are at (nλ_{g}/2, n=1, 2, 3 . . . ) from the end face of the waveguide 110 in the resonance axis direction. The conducting walls 112 are disposed at the positions of the individual nodes of the electric field of the electromagnetic waves with the oscillating frequency f_{g}. If the conducting walls 112 are disposed at all the nodes of the electric field of the electromagnetic waves with the oscillating frequency f_{g}, the distance between the conducting walls 112 is about one half of the oscillating wavelength λ_{g}.

The conducting walls 112 are disposed at positions at which the shortest distance between the conducting walls 112 and the side of the gain medium 103 is within λ_{g}/4. This configuration allows the conducting walls 112 to be close to the waveguide 110 and the gain medium 103.

When the conducting walls 112 are disposed close to the gain medium, the oscillating frequency can be stabilized. This is because, when the conducting walls 112 are disposed close to the nodes of the electric field of the electromagnetic waves with the oscillating frequency f_{g}, the waveguide loss is small, but if the conducting walls 112 are disposed close to positions that are not the nodes of the electric field of the electromagnetic waves with the oscillating frequency f_{g} (for example, the antinodes of the electric field), the waveguide loss is large. In other words, the oscillating frequency is stabilized based on the fact that when electromagnetic waves with an undesired frequency resonate in the resonator 140, the conducting walls 112 act as loss.

As described above, the resonant mode of electromagnetic waves resonating in the resonator 140, that is, a λ_{g}/2 resonant mode, a λ_{g} resonant mode, or another resonant mode, cannot be controlled. This may cause an unstable oscillating frequency. However, disposing the conducting walls 112 close to the gain medium 103 of the waveguide 110 at the positions of the nodes of the electric field of the electromagnetic waves in the resonance axis direction facilitates forming the nodes of the electric field of the electromagnetic waves at the positions of the conducting walls 112. Thus, by providing the conducting walls 112 at the positions of the nodes of the electric field of electromagnetic waves with a desired oscillating frequency f_{g}, when the waves appear stationary in the resonator 140, the nodes of the electric field of the electromagnetic waves are easily formed. This stabilizes the oscillation mode, thus stabilizing the oscillating frequency.

Although the device 100 is configured such that the capacitor 109 has the proximal regions 111, the proximal regions 111 may be separated from the capacitor 109 for suppressing parasitic oscillation. The conducting walls 112 do not need to be side walls provided along the capacitor 109 including the proximal regions 111 but may be separated from the gain medium 103. In other words, the conducting walls 112 may be disposed at appropriate positions of the dielectric layer 107. The capacitor 109 for suppressing parasitic oscillation may be either provided or not provided.

To suppress parasitic oscillation to further stabilize the oscillating frequency with the capacitor 109, the impedance of the proximal regions 111 at the desired oscillating frequency f_{g} needs to be low. Specifically, a cutoff frequency f_{c} of an RC series circuit composed of a resistor between the waveguide 110 and the proximal regions 111 and the capacitor 109 of the proximal regions 111 needs to be equal to or lower than the oscillating frequency f_{g}. The cutoff frequency f_{c} is expressed as:

f_{c}=1/(2πCR)

where C is the capacitance of the capacitor 109, and R is the resistance of the resistor.

The above configuration allows the device 100 to generate electromagnetic waves with a more stable oscillating frequency than those with conventional oscillation devices.

This embodiment includes the proximal regions 111 integrated with the capacitor 109 to provide the conducting walls 112. At the proximal regions 111, the electric potentials at the second conductor layer 102 and the third conductor layer 104 are RF-grounded, so that the voltages at the nodes of the electric field of the standing wave are stabilized both on the second conductor layer 102 and the third conductor layer 104. This allows laser oscillation at a more stable frequency.

Furthermore, in this embodiment, the waveguide 110 and the capacitor 109 are electrically connected to the conducting walls 112 by the first conductor layer 108. If the first conductor layer 108 is decreased in thickness to λ_{g}/4 or less, the inductance of the first conductor layer 108 increases. This can cause LC parasitic oscillation due to the inductance of the first conductor layer 108 and the capacitance in the gain medium. In contrast, this embodiment can decrease the inductance of the first conductor layer 108 by increasing the area of the first conductor layer 108. This can suppress LC parasitic oscillation, thus providing stable oscillation than the related art.

### First Exemplary Embodiment

In this exemplary embodiment, the oscillation device 100 in the embodiment will be described in more detail. Referring first to FIGS. 1 and 2, the configuration of the device 100 will be described.

The plasmon waveguide 110 of the resonator 140 is configured such that the second conductor layer 102, the gain medium 103, and the third conductor layer 104 are stacked in this order. The resonator 140 has a Fabry-Perot resonator structure and has at least two end faces in the resonance axis direction. Since this structure forms standing electromagnetic waves using reflection from the end faces, the length of the resonator 110 in the propagating direction determines the oscillating wavelength. In this exemplary embodiment, the length a of the waveguide 110 in the resonance axis direction was set to 102 μm, and the width b was set to 5 μm. The distance between the second conductor layer 102 and the third conductor layer 104 was as small as about 1 μm. The electromagnetic waves resonate in a plasmon mode in the resonator 140 and are radiated from the open ends of the resonator 140.

The gain medium 103 has a semiconductor layered structure including an InGaAs/InAlAs based triple-barrier resonant tunneling diode (RTD) structure that generates terahertz waves due to intersubband transition. The RTD structure is a semiconductor quantum well structure in which n-InGaAs (50 nm, Si, 2×10¹⁸ cm⁻³), InGaAs (5 nm), AlAs (1.3 nm), InGaAs (7.6 nm), InAlAs (2.6 nm), InGaAs (5.6 nm), AlAs (1.3 nm), InGaAs (5 nm), n-InGaAs (50 nm, Si, 2×10¹⁸ cm⁻³) are deposited in this order from the substrate 101.

Densely carrier-doped n+InGaAs (400 nm, 1×10¹⁹ cm⁻³) layers are disposed on and under the RTD structure. This allows the second conductor layer 102 and the third conductor layer 104 are connected to the RTD structure with low resistance so as not to cause Schottky barrier junction. The second conductor layer 102 is a stack of Ti/Pd/Au/Pd/Ti (20 nm/20 nm/400 nm/20 nm/20 nm in thickness). The third conductor layer 104 is a stack of Ti/Pd/Au (20 nm/20 nm/400 nm in thickness). The substrate 101 is a p+GaAs substrate and is connected to the second conductor layer 102.

The capacitor 109 suppresses parasitic oscillation due to the oscillation device, the power bias circuit, and so on. The capacitor 109 has a metal-insulator-metal (MIM) structure in which the dielectric film 105 is disposed between the second conductor layer 102 and the fourth conductor layer 106. The resonator 110 and the capacitor 109 are separated by the interlayer insulating layer (dielectric layer) 107 disposed therebetween but is electrically connected in parallel by the first conductor layer 108.

The fourth conductor layer 106 is a stack of Ti/Pd/Au (20 nm/20 nm/200 nm in thickness). The first conductor layer 108 is a stack of Ti/Pd/Au (20 nm/20 nm/500 nm in thickness). The dielectric film 105 is made of silicon nitride (100 nm). The interlayer insulating layer 107 may be made of an insulating material with low loss in a terahertz wave band, for example, resin, such as BCB, and an inorganic material, such as SiO₂. In this exemplary embodiment, the interlayer insulating layer 107 is made of benzocyclobutene (BCB).

The capacitance of the capacitor 109 was set to about 100 pF, and the shortest distance D1 between the capacitor 109 and the waveguide 110 was set to 25 μm. This suppresses parasitic oscillation in a frequency band of some tens of GHz. The proximal regions 111 are disposed at the positions of the nodes of the electric field of standing electromagnetic waves in the resonator 140. In this exemplary embodiment, four proximal regions 111 are provided, at both sides of the waveguide 110, at the positions of 25.5 μm and the positions of 76.5 μm from the end face of the resonator 140 in the traveling direction of the electromagnetic waves.

The proximal regions 111 each have the conducting walls 112. The conducting walls 112 are each disposed at one of the sides of the proximal region 111 closest to the waveguide 110. The proximal regions 111 are formed at the positions within λ_{g}/4 to the sides of the waveguide 110 and the gain medium 103 from the nodes of the electric field of the standing electromagnetic waves in the resonator 140, separated from the waveguide 110 by the interlayer insulating layer 107. In other words, the conducting walls 112 and the gain medium 103 of the waveguide 110 are separated by the interlayer insulating layer 107. The distance D2 between the gain medium 103 and the conducting walls 112 was set to 10 μm, which is 15 μm smaller than that of non proximal regions. In this exemplary embodiment, the width W1 of the proximal regions 111 and the conducting walls 112 in the resonance axis direction needs to be sufficiently smaller than the oscillating wavelength λ_{g}, and is preferably equal to or smaller than 1/e² of the oscillating wavelength λ_{g}. In this exemplary embodiment, the width W1 was set to 10 μm.

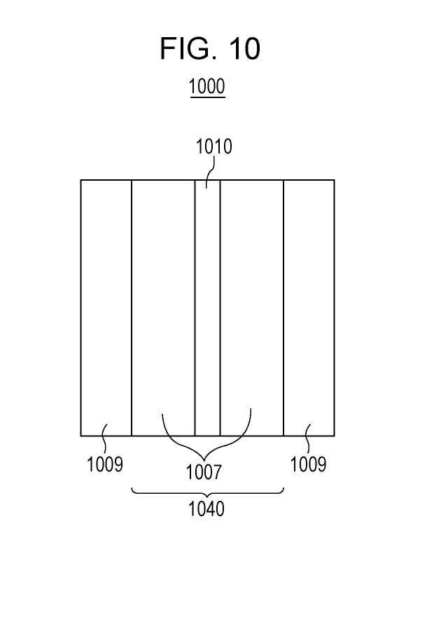

In this exemplary embodiment, a comparison is made between the oscillating frequency of the device 100 having the conducting walls 112 and the oscillating frequency of an oscillation device 1000 (hereinafter referred to as a device 1000) that has not the proximal regions 111. FIG. 10 is a top view of the configuration of the device 1000 that has not the conducting walls 112. The device 1000 has the same structure as that of the device 100 of this exemplary embodiment except that the proximal regions 111 and the conducting walls 112 are not provided. In other words, the device 1000 includes a resonator 1040 with a waveguide structure 1010 and a capacitor 1009. The capacitor 1009 and the waveguide structure 1010 are separated by an interlayer insulating layer 1007.

The lengths a of the respective resonators 140 and 1040 of the device 100 and the device 1000 were both set to 102 μm. The results of examination on oscillating frequencies produced respectively by the devices 100 and 1000 showed that the device 100 generates electromagnetic waves with a frequency of 294 GHz, and the device 1000 generates electromagnetic waves with a frequency of 213 GHz. The difference in frequency may be caused by the difference in electromagnetic-wave oscillation mode between the devices 100 and 1000.

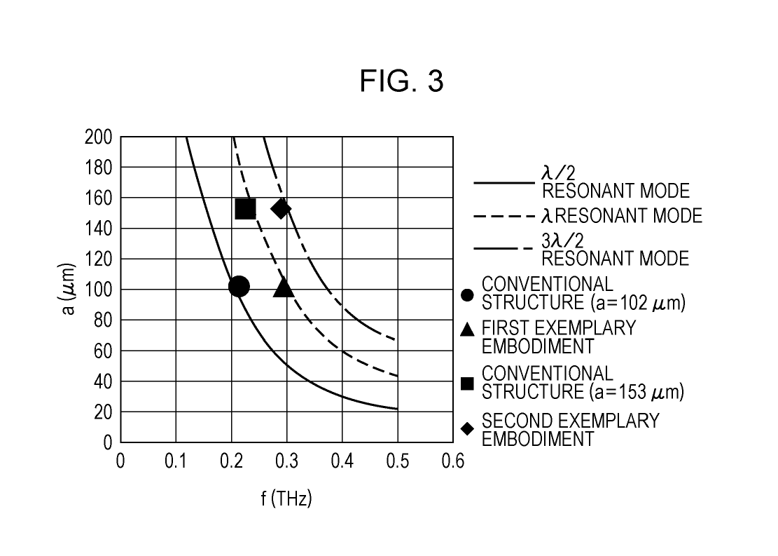

A model of the resonator 140 was produced, and the relationship among the longitudinal length a of the resonator 140, the frequency of generated electromagnetic waves, and oscillation modes (the positions of the nodes of the electric field) was examined using ANSYS HFSS. The results are shown in FIG. 3. The horizontal axis in FIG. 3 represents the frequency f, and the vertical axis represents the longitudinal length a of the resonator 140. The graph shows the results of calculation of the relationship between the frequency f and the length a when the electromagnetic waves resonate in the resonator 140 in a λ/2 resonant mode, a λ resonant mode, and a 3×λ/2 resonant mode. FIG. 3 also shows the results of calculation for the device 1000 as a comparative example.

In the λ/2 resonant mode, the length a and ½ of the wavelength λ of the oscillating electromagnetic waves are equal (a=λ/2). In the λ resonant mode, the length a and the wavelength λ of the oscillating electromagnetic waves are equal (a=2). In the 3λ/2 resonant mode, the length a and 3/2 of the wavelength λ of the generated electromagnetic waves are equal (a=3×λ/2).

The results of calculation shown in FIG. 3 show that, when each of the length a of the resonator 140, 1040 is 102 μm, the frequency f of the electromagnetic waves resonating in the λ/2 resonant mode is about 200 GHz, and the frequency f of the electromagnetic waves resonating in the λ resonant mode is about 300 GHz. The results show that the λ_{g}/2 resonant mode was selected for the electromagnetic waves with the structure of the device 1000, while the λ resonant mode was selected for the device 100 having the proximal regions 111 at the positions of the nodes of the electric field of the electromagnetic waves with the oscillating frequency f_{g} in the resonance axis direction.

Thus, when the proximal regions 111 having the conducting walls 112 at a λ_{g}/2 pitch are provided at the position of λ_{g}/4 to the side of the gain medium 103 from the end face of the waveguide 110, standing electromagnetic waves are generated at the positions of the nodes of the electric field. Thus, this exemplary embodiment can provide a more stable oscillating frequency than conventional oscillation devices.

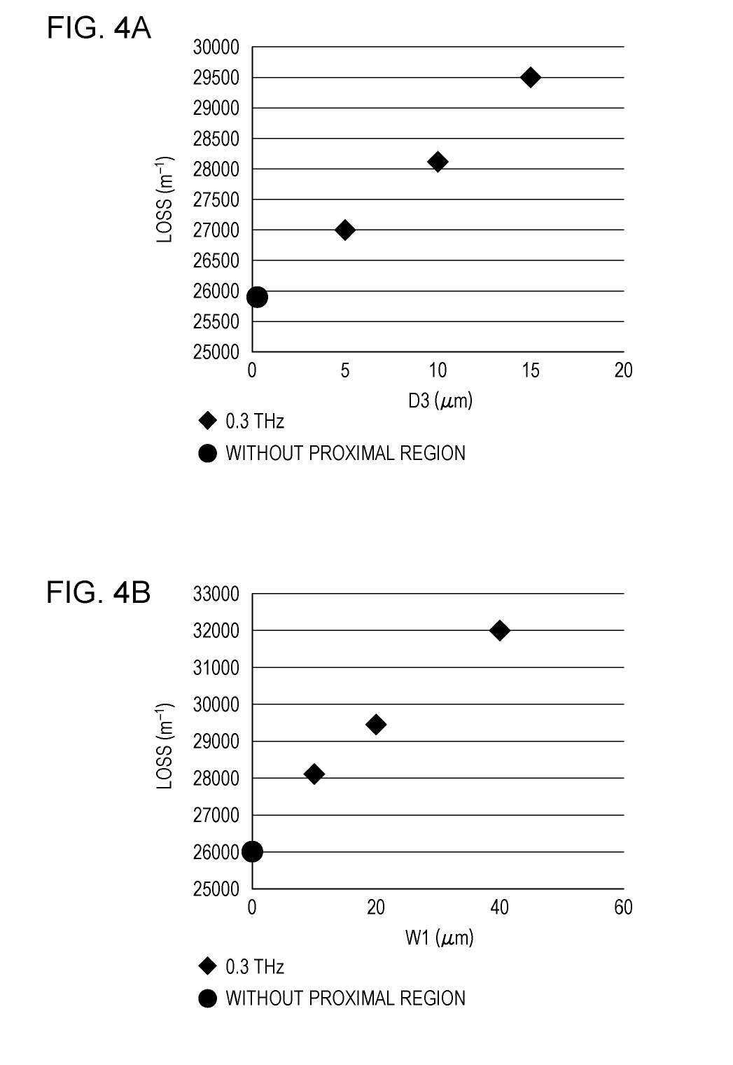

The influence of the size of the proximal regions 111 of this exemplary embodiment on waveguide loss was calculated using an electromagnetic field simulator HFSS produced by ANSYS. The results are shown in FIGS. 4A and 4B. FIG. 4A is a graph showing the relationship between the length D3 of the proximal regions 111 and waveguide loss. FIG. 4B is a graph showing the relationship between the width W1 of the proximal regions 112, that is, the width W1 of the conducting walls 112, and waveguide loss. The calculation was performed with the wavelength of the electromagnetic waves at 300 GHz.

The results show that the waveguide loss increases as the length D3 of the proximal regions 111 increases. The distance between the conducting walls 112 and the gain medium 103 decreases as the length D3 of the proximal regions 111 increases. In other words, the waveguide loss increases as the distance between the conducting walls 112 and the gain medium 103 decreases. The waveguide loss also increases as the width W1 of the conducting walls 112 increases. If the sum of the waveguide loss, reflection loss at the face end of the resonator 140, and so on is larger than the gain of the gain medium 103, the electromagnetic waves are not generated. Thus, the sizes of the conducting walls 112 and the proximal regions 111 may be determined so as not to hinder generation of electromagnetic waves.

A method for manufacturing the device 100 will be described. First, the substrate 101 made of p+GaAs is prepared, on which Ti/Pd/Au (20 nm/20 nm/200 nm in thickness) is deposited. Next, an InP substrate in which a semiconductor layer including the gain medium 103 is epitaxially grown is prepared. Thereafter, a Ti/Pd/Au metal layer (20 nm/20 nm/200 nm in thickness) is formed on the top of the semiconductor layer, and the InP substrate and the substrate 101 are joined together by an Au thermocompression bonding technique, with the InP substrate and the top of the substrate 101 opposed. The stack of Ti/Pd/Au/Pd/Ti (20 nm/20 nm/400 nm/20 nm/20 nm in thickness) formed by the compression bonding is the second conductor layer 102.

Of the two substrate formed into a single piece by bonding, the InP substrate is removed by hydrochloric acid etching, and the semiconductor layer is transferred onto the substrate 101. A stack of Ti/Pd/Au (20 nm/20 nm/400 nm) is formed as the third conductor layer 104 on the top of the transferred semiconductor layer, and the third conductor layer 104 and the gain medium 103 are patterned by photolithography and a dry etching technique. A silicon nitride film having a thickness of 100 nm is formed as the dielectric film 105 by chemical vapor deposition, and a stack of Ti/Pd/Au (20 nm/20 nm/200 nm in thickness) is formed as the fourth conductor layer 106 using a vacuum deposition technique and a lift-off technique. Thus, the capacitor 109 is formed.

Furthermore, the gain medium 103 is embedded with benzocyclobutene (BCB) by a spin coating technique and is made flat using the dry etching method to form the interlayer insulating layer (dielectric layer) 107. Next, a stack of Ti/Pd/Au (20 nm/20 nm/500 nm in thickness) is formed as the first conductor layer 108 by the vacuum deposition technique and the cut-off technique to complete the device 100.

The device 100 of this exemplary embodiment can provide a stable oscillating frequency with the configuration different from those of conventional devices. Furthermore, the device 100 has no shunt resistor in the vicinity of the waveguide 110. This prevents the operation of the oscillation device and the oscillating frequency from becoming unstable due to the effect of heat from the resistor and so on. Furthermore, this exemplary embodiment is configured such that the shape of the capacitor 109 for reducing parasitic oscillation is changed to form the proximal regions 111, part of which is located close to the gain medium 103. This can suppress parasitic oscillation to provide electromagnetic waves with a desired stable oscillating frequency f_{g}.

### Second Exemplary Embodiment

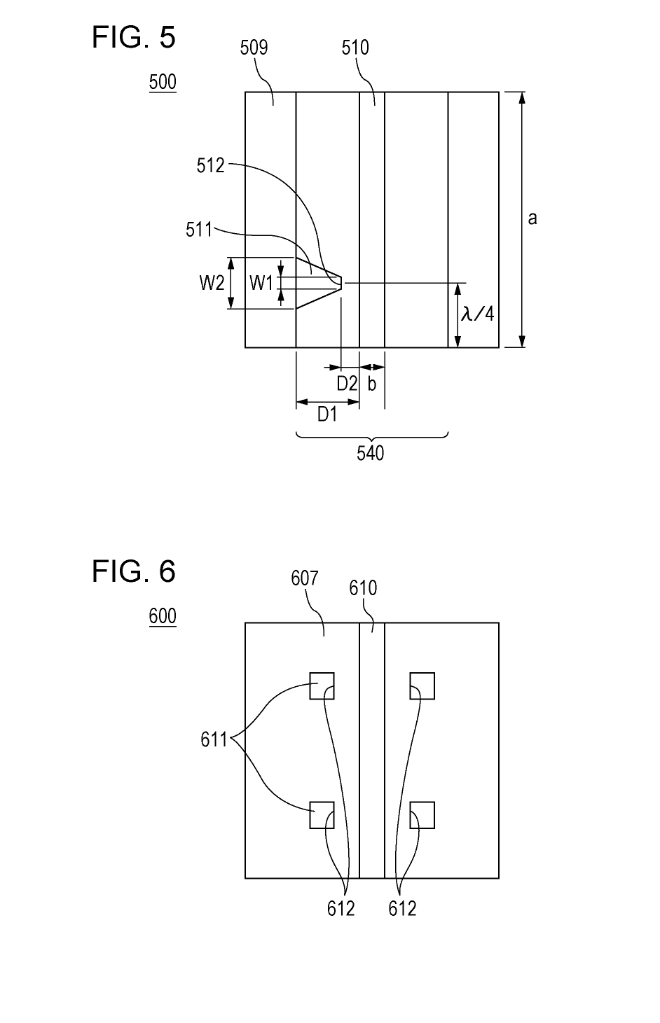

In this exemplary embodiment, a modification of the oscillation device 100 will be described. FIG. 5 is a top view of an oscillation device 500 of this exemplary embodiment (hereinafter referred to as a device 500). A resonator 540 of the device 500 differs in the length a in the resonance axis direction from the resonator 140 of the device 100, but the remaining configurations are the same. The form and number of a proximal region 511 differ from those of the proximal regions 111 of the device 100. Since the remaining configurations except those of the resonator 540 and the proximal regions 111 are the same as those of the device 100, detailed descriptions will be omitted.

The configurations of the resonator 540 and the proximal region 511 will be described. The resonator 540 includes a waveguide structure 510 (hereinafter referred to as a waveguide 510). The length a of the waveguide 510 in the resonance axis direction was set to 153 μm, and the width b was set to 5 μm.

The proximal region 511 is part of a capacitor 509. The proximal region 511 is disposed at a location of 25.5 μm in the resonance axis direction of the electromagnetic waves from an end face on one side of the waveguide 510. Although the first exemplary embodiment has a plurality of proximal regions 111 on both sides of the waveguide 110, this exemplary embodiment has only one proximal region 511 on one side of the waveguide 510.

The proximal region 511 has a trapezoidal shape whose bottom near to the waveguide 510 is shorter than a bottom nearer to the capacitor 509 in top view. The length W1 (the width of the conducting wall 512) of the bottom near to the waveguide 510 was set to 5 μm, and the length W2 of the bottom near to the capacitor 509 was set to 20 μm. The shortest distance D1 between the capacitor 509 and the waveguide 510 was set to 25 μm, and the shortest distance D2 between the proximal region 511 and the waveguide 510 was set to 5 μm. A conducting wall 512 is formed along the proximal region 511.

Also in this exemplary embodiment, a comparison is made between the oscillating frequency of the device 500 including the proximal region 511 and the oscillating frequency of the conventional device 1000 including no proximal region, as in the first exemplary embodiment. The length a of the resonator 1040 of the conventional device 1000 was set to 153 μm, which is the same as the length of the waveguide 510. The frequency of oscillating electromagnetic waves produced by the device 500 of this exemplary embodiment was 282 GHz, while the frequency of oscillating electromagnetic waves produced by the conventional device 1000 was 226 GHz.

As in the first exemplary embodiment 1, a model of the resonator 540 was produced, and the relationship among the length a of the resonator 540, the frequency of generated electromagnetic waves, and oscillation modes (the positions of the nodes of the electric field) was examined using ANSYS HFSS. As shown in FIG. 3, the device 500 generates the electromagnetic waves in the 3λ_{g}/2 resonant mode, while the conventional device 1000 generates the electromagnetic waves in the λ_{g} resonant mode. Thus, providing the proximal region 511 at the position of λ_{g}/4 from the end face of the waveguide 510, even without the λ_{g}/2 periodic structure, allows electromagnetic waves having the nodes of electric field at the position to be generated.

Thus, the device 500 can provide a stable oscillating frequency with the configuration different from the conventional configuration. Furthermore, since the shape of the proximal region 511 is designed to the shape of resonant standing waves in the waveguide 510 so as not to hinder the resonance of electromagnetic waves with the desired oscillating frequency f_{g}, electromagnetic waves with the desired oscillating frequency can be generated with more stability.

FIG. 6 is a top view of an oscillation device 600 of another modification. Proximal regions 611 may be separated from a capacitor for suppressing parasitic oscillation, as in the device 600. The proximal regions 611 may be capacitors separated from a waveguide 610 by an interlayer insulating layer 607. Conducting walls 612 are formed of the first conductor layer 108 along the outer peripheries of the proximal regions 611. The proximal regions 611 are disposed at the position of λ_{g}/4 from the end face of the waveguide 610 in the resonance axis direction and may also be formed at a λ_{g}/2 pitch. Thus, standing electromagnetic waves in the resonator 640 has the nodes of its electric field at the positions of the proximal regions 611 and resonate in the resonator 610 in a stable resonant mode. Thus, the device 600 can generate electromagnetic waves with a more stable oscillating frequency than those with conventional oscillation devices.

Thus, the device 600 can provide a stable oscillating frequency with the configuration different from the conventional configuration.

### Third Exemplary Embodiment

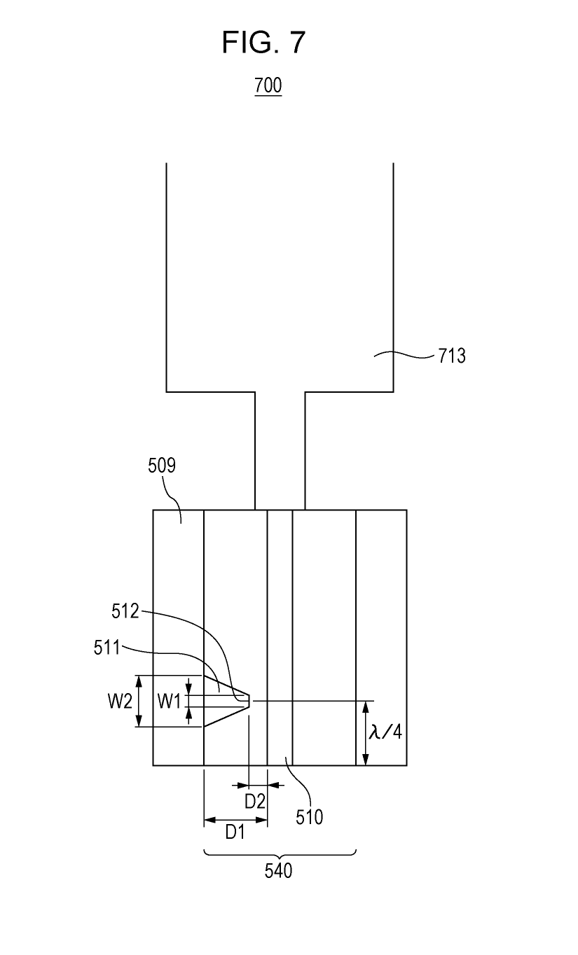

In this exemplary embodiment, an oscillator including the device 500 will be described with reference to FIG. 7. FIG. 7 is a top view of the configuration of an oscillator 700 including the device 500. The oscillator 700 includes the device 500 and a patch antenna 713 serving as a radiator for radiating electromagnetic waves. The patch antenna 713 is disposed at an end face of the waveguide 510. By providing a structure (the patch antenna 713) for extracting standing electromagnetic waves in the resonator 540 at an end face of the waveguide 510, the oscillator 700 can also be used as a light source for performing imaging and communications.

Thus, this exemplary embodiment can provide a stable oscillating frequency with the configuration different from the conventional configuration.

### Fourth Exemplary Embodiment

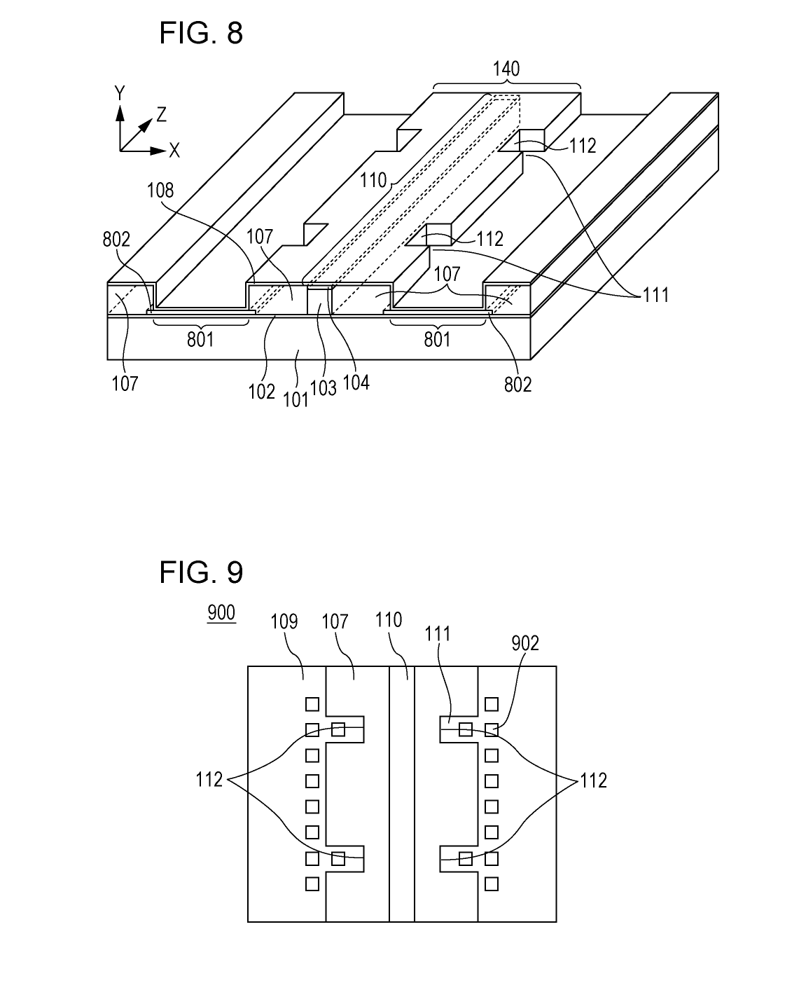

An oscillation device 800 according to this exemplary embodiment will be described with reference to FIG. 8. FIG. 8 is a diagram illustrating the configuration of the oscillation device 800. The oscillation device 800 differs from the first exemplary embodiment in that the oscillation device 800 includes a shunt resistor 801 instead of the capacitor 109. The structures of the waveguide 110, the gain medium 103, the second conductor layer 102, the third conductor layer 104, and the first conductor layer 108 are the same as those in the first exemplary embodiment.

The shunt resistor 801 includes the second conductor layer 102, the first conductor layer 108, and a resistor 802 disposed between the second conductor layer 102 and the first conductor layer 108. The resistor 802 is a conductor and specifically may be made of metal, ceramic, semiconductor, or the like. The resistor 802 may also be a stack of metal, ceramic, semiconductor, and so on. The shunt resistor 801 suppresses parasitic oscillation due to the oscillation device 800, the bias circuit, and so on.

The waveguide 110 and the shunt resistor 801 are separated by the dielectric layer 107 but are electrically connected in parallel by the second conductor layer 102 and the first conductor layer 108. The sum of the resistance of the shunt resistor 801 and the resistance of the wire of the first conductor layer 108 connecting the plasmon waveguide 110 and the shunt resistor 801 may be set to be smaller than the absolute value of the differential negative resistance of the gain medium 103. The sum resistance can be adjusted based on the materials and the thicknesses of the shunt resistor 801 and the first conductor layer 108 and the disposition and the shape of the shunt resistor 801. In this exemplary embodiment, since the differential negative resistance of the gain medium 103 was −0.45Ω, the resistance of the shunt resistor 801 was set to 0.16Ω. The resistor 802 may be eliminated, and the second conductor layer 102 and the first conductor layer 108 may be in direct contact with each other.

In this exemplary embodiment, the length a of the waveguide 110 was set to 102 μm, and the width b was set to 5 μm. As in the first exemplary embodiment, the proximal regions 111 including the conducting walls 112 were provided so that the electromagnetic waves in the resonator 140 resonate in the λ resonant mode. Specifically, the conducting walls 112 were provided at the position of λ_{g}/4 and the position of 3λ_{g}/4 from the end face of the resonator 140 in the traveling direction of the electromagnetic waves.

The position of λ_{g}/4 and the position of 3λ_{g}/4 from the end face of the resonator 140 in the traveling direction of the electromagnetic waves are respectively the positions of 25.5 μm and 76.5 μm from one of the end faces of the resonator 140. In this exemplary embodiment, the conducting walls 112 were provided on both sides of the waveguide 110. The oscillating frequency of the electromagnetic waves in this case was about 300 GHz, and the electromagnetic waves oscillate in the λ resonant mode as in the first exemplary embodiment. The distance D1 between the waveguide 110 and the shunt resistor 801 was set to 25 μm. This configuration provides a stable oscillating frequency with the configuration different from the conventional configuration.

If the wire of the first conductor layer 108 connecting the shunt resistor 801 and the plasmon waveguide 110 is thin, for example, λ_{g}/4 or less, the inductance of the first conductor layer 108 is large. This may cause LC parasitic oscillation due to the inductance of the first conductor layer 108 and the capacitance in the gain medium 103. In contrast, in this exemplary embodiment, the inductance of the first conductor layer 108 can be decreased by increasing the cross section of the wire formed of the first conductor layer 108 connecting the shunt resistor 801 and the waveguide 110. This allows the LC parasitic oscillation to be suppressed, providing stable oscillation.

### Fifth Exemplary Embodiment

An oscillation device 900 of this exemplary embodiment will be described with reference to FIG. 9. FIG. 9 is a diagram illustrating the configuration of the oscillation device 900. In this exemplary embodiment, shunt resistors are provided along the conducting walls 112 and the proximal regions 111 by disposing a plurality of resistors 902 passing through part of the dielectric film 105. The resistors 902 are the same as the resistors 802 in the fourth exemplary embodiment. Examples of the shape of the plurality of resistors 902 include a rectangle 2 μm each side or a circle with a diameter of 2 μm. Such a configuration in which shunt resistors are disposed in part of the proximal regions 11 can stabilize the oscillating frequency with the configuration different from the conventional configuration.

Although an embodiment and exemplary embodiments of the present invention have been described, it is to be understood that the present invention is not limited thereto, and various modifications and changes can be made within the scope of the spirit and scope of the invention. For example, the above embodiment and the first and second exemplary embodiments have respectively the capacitors 109 and 509 for suppressing parasitic oscillation; alternatively, a configuration including no capacitor is possible, as in the third exemplary embodiment. As shown in the second exemplary embodiment, the shapes and sizes of the conducting wall and the proximal region can be changed as appropriate. The shapes of the conducting walls and the proximal regions may be designed to the shape of a standing electromagnetic wave resonating in the resonator. Specifically, the shapes of the conducting walls and the proximal regions may be adjusted to shapes that do not interfere the resonance of the standing electromagnetic waves in the resonator.

To stabilize the oscillating frequency, the conducting walls 112 may be disposed at predetermined positions. For example, even without the capacitor like the proximal regions 111, conductors may be embedded at the positions of the nodes of the electric field of the electromagnetic waves in the resonance axis direction in the interlayer insulating layer 107 so as to function as conducting walls for stabilizing the oscillating frequency.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-156795, filed Jul. 31, 2014, and No. 2015-120404, filed Jun. 15, 2015, which are hereby incorporated by reference herein in their entirety.

What is claimed is:

1. An oscillation device that produces an oscillating electromagnetic wave, comprising:
a resonator including a waveguide structure for resonating the electromagnetic wave along a resonance axis direction and including a dielectric layer;
a conducting wall; and
a first conductor layer that electrically connects the waveguide structure and the conducting wall,
wherein the waveguide structure includes a second conductor layer, a gain medium disposed on the second conductor layer, and a third conductor layer disposed on the gain medium;
the dielectric layer is disposed on the second conductor layer and along a side of the gain medium;
the conducting wall is separated from the gain medium by the dielectric layer and is disposed at a position of a node of an electric field of the electromagnetic wave appearing to be stationary in the waveguide structure in the resonance axis direction; and
an optical distance between the side of the gain medium and the conducting wall is equal to or smaller than one fourth of a wavelength of the electromagnetic wave.

2. The oscillation device according to claim 1, wherein:
the waveguide structure has an end face that is an open end; and
an optical distance between the conducting wall and the end face is one fourth of the wavelength of the electromagnetic wave.

3. The oscillation device according to claim 1, wherein:
the waveguide structure has an end face that is a fixed end; and
an optical distance between the conducting wall and the end face is one half of the wavelength of the electromagnetic wave.

4. The oscillation device according to claim 1, comprising a plurality of the conducting walls.

5. The oscillation device according to claim 4, wherein, among the plurality of conducting walls, a distance between two conducting walls closest to each other in the resonance axis direction is one half of the wavelength of the electromagnetic wave.

6. The oscillation device according to claim 1, further comprising a first capacitor including the second conductor layer, a dielectric film disposed on the side of the gain medium and on the second conductor layer, and a fourth conductor layer disposed on the dielectric film,
wherein the first capacitor and the waveguide structure are electrically connected by the first conductor layer;
the first capacitor includes a proximal region that is part of the first capacitor close to the gain medium; and
the first conductor layer constitutes the conducting wall along the proximal regions.

7. The oscillation device according to claim 6, wherein
a cutoff frequency f_{c} of an RC series circuit based on a resistor between the waveguide structure and the conducting wall and the first capacitor is expressed as:
f_{c}=1/(2πCR)
where R is a resistance of the resistor between the waveguide structure and the conducting wall, and C is a capacitance of the first capacitor; and
the capacitance C is set so that the cutoff frequency f_{c} is equal to or lower than an oscillating frequency f_{g} of the electromagnetic wave.

8. The oscillation device according to claim 6, further comprising a second capacitor separated from the first capacitor by the dielectric layer and electrically connected to the waveguide structure and the first capacitor by the first conductor layer,
wherein a cutoff frequency f_{c} of an RC series circuit based on a resistor between the waveguide structure and the conducting wall and the second capacitor is expressed as:
f_{c}=1/(2πCR)
where R is a resistance of the resistor between the waveguide structure and the conducting wall, and C is a capacitance of the second capacitor; and
the capacitance C is set so that the cutoff frequency f_{c} is equal to or lower than an oscillating frequency f_{g} of the electromagnetic wave.

9. The oscillation device according to claim 1, further comprising a first capacitor including the second conductor layer, a dielectric film disposed on the side of the gain medium and on the second conductor layer, and a fourth conductor layer disposed on the dielectric film,
wherein the first capacitor and the waveguide structure are electrically connected by the first conductor layer; and
the first conductor layer constitutes the conducting wall along the first capacitor.

10. The oscillation device according to claim 9, wherein
a cutoff frequency f_{c} of an RC series circuit based on a resistor between the waveguide structure and the conducting wall and the first capacitor is expressed as:
f_{c}=1/(2πCR)
where R is a resistance of the resistor between the waveguide structure and the conducting wall, and C is a capacitance of the first capacitor; and
the capacitance C is set so that the cutoff frequency f_{c} is equal to or lower than an oscillating frequency f_{g} of the electromagnetic wave.

11. The oscillation device according to claim 9, further comprising a second capacitor separated from the first capacitor by the dielectric layer and electrically connected to the waveguide structure and the first capacitor by the first conductor layer,
wherein a cutoff frequency f_{c} of an RC series circuit based on a resistor between the waveguide structure and the conducting wall and the second capacitor is expressed as:
f_{c}=1/(2πCR)
where R is a resistance of the resistor between the waveguide structure and the conducting wall, and C is a capacitance of the second capacitor; and
the capacitance C is set so that the cutoff frequency f_{c} is equal to or lower than an oscillating frequency f_{g} of the electromagnetic wave.

12. The oscillation device according to claim 1, further comprising a resistor disposed on the side of the gain medium and on the second conductor layer,
wherein the resistor and the waveguide structure are electrically connected by the first conductor layer;
the resistor includes a proximal region that is part of the resistor close to the gain medium; and
the first conductor layer constitutes the conducting wall along the proximal region.

13. The oscillation device according to claim 1, wherein the conducting wall has a length in the resonance axis direction of 1/e² or less of the wavelength of the electromagnetic wave.

14. The oscillation device according to claim 1, wherein the waveguide structure is a plasmon waveguide structure in which the second conductor layer and the third conductor layer have a real part of dielectric constant including a negative dielectric constant medium.

15. The oscillation device according to claim 1, wherein the gain medium includes a semiconductor multilayer with a quantum well structure that generates the electromagnetic wave by carrier intersubband transition.

16. The oscillation device according to claim 1, wherein the electromagnetic wave has a frequency of 30 GHz or higher and 30 THz or lower.

17. An oscillator comprising the oscillation device according to claim 1 and a radiator that radiates an electromagnetic wave from the oscillation device.

18. The oscillator according to claim 17, wherein the radiator is a patch antenna.
